(19) United States
(12) Patent Application Publication
(10) Pub. No.: US 2003/0097623 A1
(43) Pub. Date: May 22, 2003

(54) Method and apparatus for performance optimization and adaptive bit loading for wireless modems with convolutional coder, FEC, CRC and ARQ

(76) Inventors: Javad Razavilar, San Diego, CA (US); Dennis P. Connors, San Diego, CA (US); James A. Crawford, San Diego, CA (US); Celio V. Albuquerque, Encinitas, CA (US)

Correspondence Address: FITCH EVEN TABIN AND FLANNERY, 120 SOUTH LA SALLE STREET, SUITE 1600, CHICAGO, IL, 60603-3406, US

(21) Appl. No.: 09/999,516

(22) Filed: Oct. 24, 2001

(51) Int. Cl. G06F 11/00; G11C 29/00

(52) U.S. Cl. 714/704

(57) ABSTRACT

A closed form solution is provided in a receiver, such as an OFDM receiver, including the step of determining an uncoded bit error rate (BER) at an output of a demodulator of a receiver based upon at least a target BER to be achieved after the completion of forward error correction at the receiver. In a variation, the solution is used to provide an optimum bit loading algorithm designed to meet the target BER and including the steps of: measuring a channel condition metric corresponding to a signal received from a transmitter at a receiver via a communication channel; and determining an optimum number of bits/symbol supportable by the communication channel based upon at least the measured channel condition metric and the target BER. In some variations, these closed form solutions may be performed offline and stored in the receiver as a lookup table.

### BACKGROUND OF THE INVENTION

1. Field of the Invention

The present invention relates generally to the optimization of throughput in a communication system, and more specifically to the optimization of throughput while achieving performance requirements in terms of a required target bit error rate (BER) at the output of a receiver. Even more specifically, the present invention relates to the optimization of throughput depending on channel conditions while meeting the required target BER at the receiver.

2. Discussion of the Related Art

In any communication system there is a performance requirement in terms of target bit error rate (BER) that needs to be achieved. Usually the performance requirement for communication systems is defined as the target BER pₜ at the output of the system after all signal processing including all levels of forward-error-corrections (FEC) and automatic repeat request (ARQ) are completed.

In many communication systems, particularly systems supporting multiple data rates, it is desirable to maximize resources and/or optimize system throughput. Throughput is a function of the signal-to-interference ratio (SIR) and the modulation scheme used and may be defined as the number of bits that can be transmitted successfully to a receiver within each symbol. One technique to optimize throughput is to use adaptive bit loading or adaptive modulation at a modulator of a transmitter to change the number of bits assigned to a carrier as channel conditions change, i.e., change the modulation depending on the channel conditions. The basic idea in adaptive bit loading is to vary the number of bits assigned while meeting the required target BER at the output of the receiver. For example, in any given channel condition, it is desirable to transmit as many bits as possible while meeting the target BER.

In many communication systems, particularly wireless communication systems, the channel between a given transmitter and a given receiver may be time variant and unreliable; thus, meeting the target BER may be a difficult task. In order to meet the required target BER even during periods of poor channel conditions, most systems introduce a gain margin in the system, e.g., a gain margin of 7-8 dB. Thus, the signaling is transmitted at a higher than specified power level to ensure that the required target BER is met. Furthermore, even though most communication standards already include a gain margin, system designers often add additional gain margin as a cushion. Although the introduction of a gain margin is effective in meeting the required target BER, it represents a waste of system resources or an “overengineering” of the system and leads to expensive receiver designs. This is particularly problematic with wireless channels where every dB is important, such that introducing unnecessary gain margins represents a waste of valuable resources.

One approach to determine the number of bits to assign to a carrier based on channel conditions is a simple trial and error approach where a number of bits per carrier is assigned, then moving forward in the system, the BER is measured at the output of the receiver to determine if the target BER has been met. Another approach involves using Shannon Channel capacity equation to theoretically determine the number of bits to assign to a carrier. However, these approaches still employ a gain margin (i.e., an SNR gap) to ensure that the target BER is met at the receiver; thus, wasting system valuable resources. Furthermore, these approaches do not provide a closed form solution to the problem.

In any communication system with adaptive modulation using, for example, an M-ary Quadrature Amplitude Modulation (M-QAM) scheme, the throughput can be maximized by selecting the proper modulation scheme according to the channel conditions. For this purpose, the “raw” or “uncoded” bit error rate should be known. The uncoded BER is the bit error rate at the output of the demodulator of a receiver and before forward error correction (FEC) and automatic repeat request (ARQ). It would be desirable to determine the uncoded BER so that the transmitter can choose the proper number of bits to transmit (i.e., which modulation to use) without introducing an unnecessary gain margin (SNR gap) to meet the required target BER at the output of the system.

### SUMMARY OF THE INVENTION

The present invention advantageously addresses the needs above as well as other needs by providing a closed form solution to determine the uncoded bit error rate (BER) at the output of a demodulator given a target BER to be met at the receiver and an optimum bit loading algorithm derived from the uncoded BER.

In one embodiment, the invention can be characterized as a method including the steps of: obtaining a target bit error rate required at a receiver; and determining an uncoded bit error rate at an output of a demodulator of the receiver based upon at least the target bit error rate, the target bit error rate defined as the bit error rate to be achieved after the completion of forward error correction at the receiver.

In another embodiment, the invention can be characterized as a method including the steps of: measuring a channel condition metric corresponding to a signal received from a transmitter at a receiver via a forward communication channel; and determining an optimum number of bits/symbol supportable by the forward communication channel based upon at least the measured channel condition metric and a target bit error rate to be met at the receiver.

In a further embodiment, the invention may be characterized as a receiver in a communication system including a channel metric estimation module for measuring a channel condition metric corresponding to a signal received from a communication channel. Also included is a rate optimization module for determining an optimum number of bits/symbol supportable by the communication channel based upon at least the measured channel condition metric and a target bit error rate to be met at the receiver.

### BRIEF DESCRIPTION OF THE DRAWINGS

The above and other aspects, features and advantages of the present invention will be more apparent from the following more particular description thereof, presented in conjunction with the following drawings wherein:

FIG. 1 is a functional block diagram illustrating several components of the physical (PHY) layer and data link control layer (or medium access control (MAC) layer) for data transmission between a transmitter and receiver over a communication channel according to one embodiment of the invention;

FIG. 2 is a flowchart illustrating the steps performed in deriving the relationship between an uncoded BER at the output of a demodulator of the receiver of FIG. 1 in terms of a target BER at the completion of signal processing including forward error correction and automatic repeat request according to one embodiment of the invention;

FIG. 3 is a simplified block diagram of a communication system including a transmitter and a receiver communicating over forward and reverse communication channels and implementing several embodiments of the invention;

FIG. 4 is a block diagram of one embodiment of the receiver of FIG. 3 used to determine an optimum number of bits/symbol supportable by the communication channel for communications from the transmitter based on measurements of the channel conditions at the receiver; and

FIG. 5 is a flowchart illustrating the steps performed by the receiver of FIG. 4 according to one embodiment of the invention.

Corresponding reference characters indicate corresponding components throughout the several views of the drawings.

### DETAILED DESCRIPTION

The following description is not to be taken in a limiting sense, but is made merely for the purpose of describing the general principles of the invention. The scope of the invention should be determined with reference to the claims.

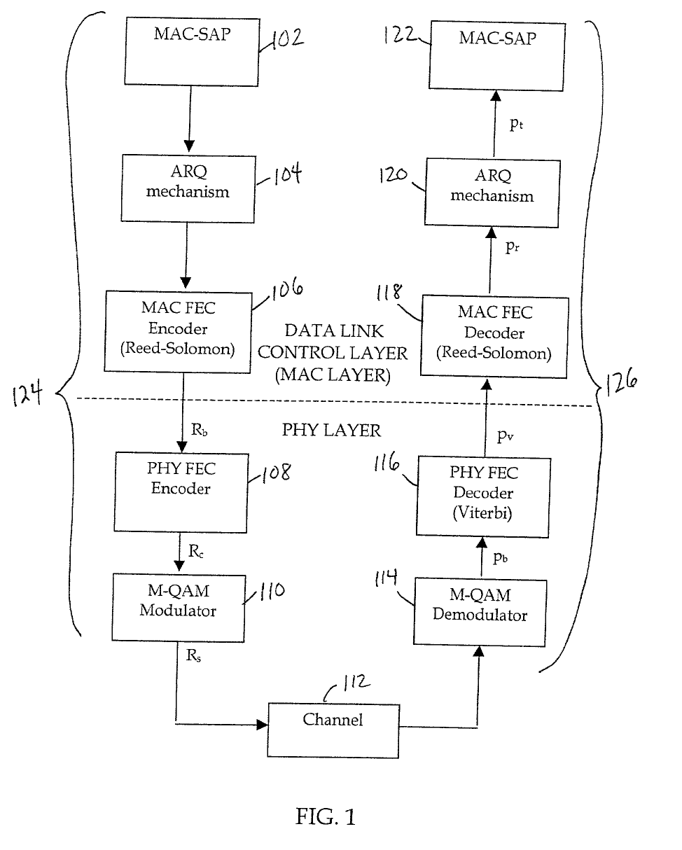

Referring first to FIG. 1, a functional block diagram is shown that illustrates several components of the physical (PHY) layer and data link control layer (DLC) layer (or medium access control (MAC) layer) for data transmission between a transmitter and receiver over a communication channel according to one embodiment of the invention. The communication system 100 includes a transmitter 124 and a receiver 126. The transmitter 124 includes MAC-service access point layer 102 (hereinafter referred to as MAC-SAP layer 102), an automatic repeat request mechanism 104 (hereinafter referred to as ARQ mechanism 104), a MAC forward error correction encoder 106 (hereinafter referred to as MAC FEC encoder 106), a PHY FEC encoder 108 and a modulator 110. Signaling from the transmitter 124 to the receiver 126 is sent via the communication channel 112 (also referred to as the forward communication channel or simply channel 112). The receiver 126 includes a demodulator 114, a PHY FEC decoder 116, a MAC FEC decoder, an automatic repeat request mechanism 120 (hereinafter referred to as ARQ mechanism 120), and MAC-SAP layer 122.

The system illustrated in FIG. 1 represents a general example of a communication system transmitting from a transmitter to a receiver. The system 100 includes components in the data link control layer (also referred to as the MAC layer) and in the physical (PHY) layer. At the transmitter 124, the ARQ mechanism 104 and the MAC FEC encoder 106 are in the data link control layer while the PHY FEC encoder 108 and the modulator 110 are in the PHY layer. Similarly, at the receiver 126, the ARQ mechanism 120 and the MAC FEC decoder 118 are in the data link control layer while the PHY FEC decoder 116 and the demodulator 114 are in the PHY layer. The functionality of each of these components is well known in the art.

It is noted that the forward error correction mechanisms illustrated are present in both the physical (PHY) layer and the MAC layer; however, it is not required that forward error correction be present in both layers. Thus, if used, FEC mechanisms may be used in one or both of the PHY layer and the MAC layer. Furthermore, the MAC FEC encoder 106 and MAC FEC decoder 118 may be any type of forward error correction known in the art for the MAC layer, such as Reed-Solomon encoding along with an added cyclic redundancy check (CRC). Similarly, the PHY FEC encoder 108 and the PHY FEC decoder 116 may be any type of forward error correction known in the art for the PHY layer, such as convolutional encoding. For example, in one embodiment, the PHY FEC encoder is a convolutional encoder and the PHY FEC decoder is a convolutional decoder, such as a Viterbi decoder.

At the transmitter 124, data is organized into packets and placed on frames by the MAC-SAP layers 102. The ARQ mechanism 104 adds the desired type of automatic repeat request, such as selective repeat ARQ. The MAC FEC encoder 106 adds an error protection scheme, such as Reed-Solomon coding with some type of cyclic redundancy check (CRC) for each frame. The PHY FEC encoder 108 is coupled to the output of the MAC FEC encoder 106 and adds a physical layer error protection scheme according to any known technique. The modulator 110 is coupled to the output of the PHY FEC encoder 108 and maps the data for transmission according to any modulation scheme. In one embodiment, the transmitter is an OFDM transmitter adapted to accommodate multiple data rates according to an M-ary Quadrature Amplitude Modulation or M-QAM (e.g., BPSK, QPSK, 16-QAM, 64-QAM, 128-QAM, etc.) modulation scheme.

The data frame is then transmitted to the receiver 126 via the channel 112. At the receiver 126, the demodulator 114 demaps the modulated data frame. The PHY FEC decoder 116 then decodes the physical layer coding scheme, for example, decodes received codewords, for example, using a Viterbi decoder. At the data link control layer or MAC layer, the MAC FEC decoder 118 corrects errors and passes the data frame along to the ARQ mechanism 120. As is well known, the ARQ mechanism 120 provides either a positive or negative acknowledgement to transmit back to the ARQ mechanism 104 of the transmitter 124 depending on whether the frame was received in error. The data frame is finally passed to the MAC-SAP layer 122.

Many communication systems define a required target bit error rate (BER) to be met. The coded or target BER, pₜ, is defined as the BER at the output of the communication system after the completion of forward error correction (e.g., at one or more of the PHY layer and the MAC layer) and other signal processing levels in the data link control layer are completed, such as, ARQ. Thus, the target BER is illustrated in FIG. 1 as pₜ at the output of the ARQ mechanism 120. It is noted that for communication systems not including an ARQ mechanism at the transmitter 124 and receiver 126, the target BER pₜ is would be at the output of the MAC FEC decoder 118.

In many communication systems, the conditions of the channel 112 greatly affect the data throughput from the transmitter 124 to the receiver 126 and the ability to meet the target BER. This is particularly true in the case of wireless channels. In some wireless systems, channel conditions can change very rapidly and dramatically. By way of example, in indoor wireless local area networks (LAN), the channel 112 is affected by the multipath environment and potentially mobile communicating devices.

One method to maximize or optimize throughput in such a system is to use adaptive bit loading or adaptive modulation at the transmitter 124. In adaptive bit loading, the modulator 110 changes the number of bits assigned to a given symbol depending on the channel conditions while meeting the required target BER at the receiver 126. This allows for more data to be sent when the channel conditions are good and less data to be sent when channel conditions are poor while still meeting the target BER pt. Many system designers introduce a gain margin (or SNR gap) into the system in order to ensure that the target BER is met. In wireless communication systems, such as wireless LAN, this gain margin allows a designer to meet the required target BER, however, at the cost of wasting valuable system resources. Additionally, this leads to expensive receiver designs.

Advantageously, in many communication systems, if the BER at the output of the demodulator 114, i.e., the uncoded BER p_{b}, is known, the modulator 110 at the transmitter 124 can choose the proper number of bits to assign to the symbols without having to introduce unnecessary gain margins in order to meet the target BER. Thus, the throughput of the system 100 can be optimized for all channel conditions without wasting valuable resources. This would reduce the cost of a receiver in such a system in comparison to systems that simply introduce a gain margin to meet the target BER.

According to one embodiment of the invention, a closed form solution is provided to determine the uncoded BER p_{b} given the target BER specified by the communication standard. This closed form solution is then used to provide an optimum adaptive bit loading algorithm in order to ensure that the system will meet the target BER pₜ without introducing unnecessary margins. Thus, the optimum number of bits/symbol is determined based upon the channel conditions. It is noted that depending on the embodiment, each symbol may be transmitted according to a single carrier transmission scheme or a multicarrier (e.g., including multiple subcarriers) transmission scheme, where one M-QAM symbol is transmitted per each subcarrier. In preferred embodiments, the solution and adaptive bit loading algorithm are designed for wireless LAN applications using orthogonal frequency division multiplexing (OFDM) with a variable M-ary quadrature amplitude modulation (M-QAM) scheme for each subcarrier. Thus, in preferred embodiments, the optimum number of bits/subcarrier is determined. Furthermore, in several embodiments of the invention, the provided closed form solutions may be performed offline for many different variables and stored as a lookup table in memory at the receiver. Thus, the receiver can easily look up the uncoded BER and/or the optimum number of bits to assign per symbol.

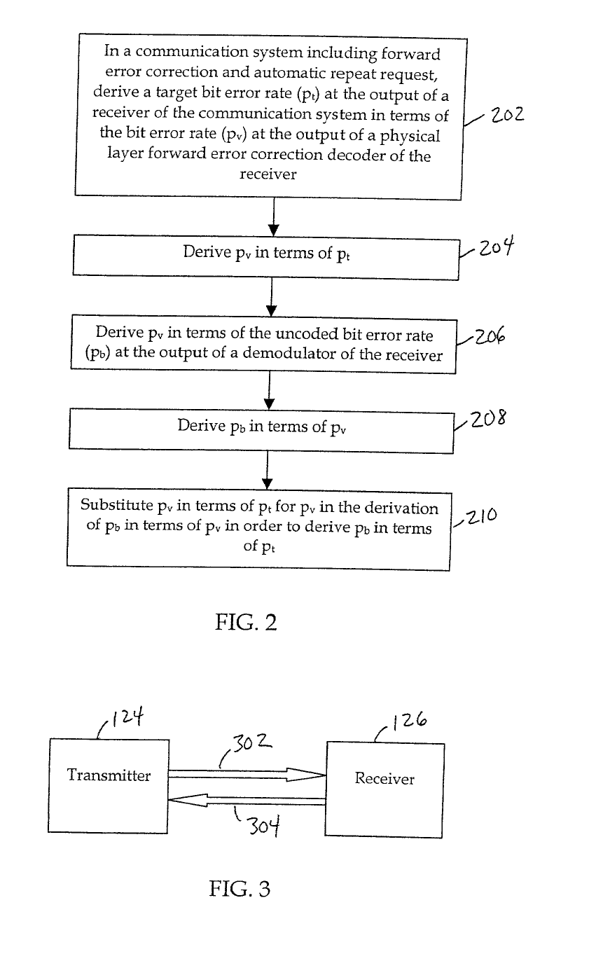

Referring concurrently to FIG. 2, a flowchart is shown that illustrates the steps performed in reaching the closed form solution for the uncoded BER at the output of a demodulator of the receiver of FIG. 1 in terms of a target BER according to one embodiment of the invention.

Initially, the target BER is defined for a communication system including forward error correction (FEC) and ARQ. As stated above, the FEC mechanisms may be implemented in one or more of the PHY layer and the MAC layer. For any given system, the target BER is defined in the standard, e.g., the target BER may be 10⁻⁷, 10⁻⁸ or 10⁻⁹. As shown in FIG. 1, the target BER pₜ is shown at the output of ARQ mechanism 120. It is noted that in embodiments not using ARQ, the target BER would be at the output of the MAC FEC decoder 118.

Initially, the target BER is derived in terms of the BER at the output of the PHY FEC decoder 116 (also referred to as the PHY decoder BER or pᵥ) (Step 202 of FIG. 2). According to one embodiment, it is assumed that Reed-Solomon encoding is used in the MAC FEC encoder 106 in combination with a cyclic redundancy check (CRC) added to each frame that is transmitted to the receiver via the channel 112. Thus, a frame length N bits has an information field of the length K RS bits (K Reed-Solomon bits), a CRC field of the length c bits, and a redundancy field of the length d bits, i.e., N=K+c+d. The length d determines the number of bit errors that the MAC FEC decoder 118 (Reed-Solomon) can correct, t, such that

$$t = ⌊ \frac{d + 1}{2} ⌋ .$$

The larger the redundancy field d, the larger the number of errors t that can be corrected. Also, the physical (PHY) layer adds another level of redundancy to protect the information bits transmitted over the wireless channel 112. At the transmitter 124 side, the PHY FEC encoder 108, in one embodiment a convolutional encoder, takes Kᵥ information bits and generates a codeword of length Nᵥ. At the receiver 126 side, the received codewords are decoded at the PHY FEC decoder 116, for example, using convolutional decoder, such as a Viterbi decoder. As illustrated in FIG. 1, pᵥ denotes the BER at the output of the PHY FEC decoder 116 (in this embodiment, the Viterbi decoder).

Assuming that the FEC decoder 118 can correct any frame with less than or equal to t bits in error and pass the frame as a good frame to the higher layers (i.e., the MAC-SAP layers 122). Therefore, the frame-error-rate (FER) at the output of the MAC FEC decoder 118 (illustrated in FIG. 1 as pᵣ) is defined below in Equation (1) (hereinafter referred to as Eq. (1)):

$${p}_{r} = {{\sum }^{N}}_{l = t + 1} ( \begin{matrix}N \\ l\end{matrix} ) {{p}_{v}^{l} ( 1 - {p}_{v} )}^{N - l} \qquad Eq . ( 1 )$$

where N is the length of the frame in bits, t is number of bit errors correctable by the MAC FEC decoder 118 and pᵥ is the BER at the output of the PHY FEC decoder 116. Thus, the probability that a frame is error-free at the output of the MAC FEC decoder 118 is (1−pᵣ). In the event, there are greater than t bit errors are received, the MAC FEC decoder 118 will not be able to correct them and the CRC (testing frame integrity) will fail, which will cause the ARQ mechanism 120 to request that the frame be retransmitted. Using the ARQ mechanism 120, the frame can be transmitted up to k times. According to one embodiment, the average number of transmissions, λ, needed before the frame is passed to the MAC-SAP layer 122 will be:

λ=(1−pᵣ)+2pᵣ(1−pᵣ)+3pᵣ²(1−pᵣ)+ . . . +kpᵣ^{k-1}(1−pᵣ)+kpᵣ^{k} Eq. (2)

This simply means that a given frame is either error free at the output of the MAC FEC decoder 118 after the first transmission, or the second transmission, or the k^{th} transmission, or it will be passed as a bad frame to the MAC-SAP layer 122 if it still contains more than t errors after the k^{th} transmission. Intuitively, for large values of k, Eq. (2) reduces to

$$λ = \frac{1}{1 - {p}_{r}} .$$

In the event there is no ARQ mechanism 120, i.e., k=1, then Eq. (2) becomes λ=1. In a more rigorous manner, Eq. (2) sums up to:

$$λ = \frac{1 - {p}_{r}^{k}}{1 - {p}_{r}} \qquad Eq . ( 3 )$$

In one embodiment, the coded BER, pₜ, after all FEC/ARQ processes for k transmissions are complete is computed in the following manner. The probability that a given frame contains more than l>t bit errors at the output of MAC FEC decoder 118 after k^{th} transmission is given by:

$${e}_{l} = {p}_{r}^{k - 1} ( \begin{matrix}N \\ l\end{matrix} ) {{p}_{v}^{l} ( 1 - {p}_{v} )}^{N - l} \qquad Eq . ( 4 )$$

Eq. (4) indicates that more than t errors were found in the frame in each of the first k−1 transmissions, and l>t errors were found after the last allowed transmission (k^{th} transmission). Therefore, the coded or target BER, pₜ, in a communication system including ARQ in terms of pᵥ (Step 202 of FIG. 2) is then given by:

$${p}_{t} = \frac{1}{N} {{\sum }^{N}}_{l = t + 1} l \cdot {e}_{l} = {[ {{\sum }^{N}}_{l = t + 1} ( \begin{matrix}N \\ l\end{matrix} ) {{p}_{v}^{l} ( 1 - {p}_{v} )}^{N - l} ]}^{k - 1} [ {{\sum }^{N}}_{l = t + 1} ( \begin{matrix}N - 1 \\ l - 1\end{matrix} ) {{p}_{v}^{l} ( 1 - {p}_{v} )}^{N - l} ] \qquad Eq . ( 5 )$$

where N is the length of the frame in bits, t is number of bit errors correctable by the MAC FEC decoder 118, k is the number of transmissions using ARQ, l is the number of bit errors, pᵥ is the PHY decoder BER, and eₗ is the probability that a given frame contains more than l>t bit errors at the output of MAC FEC decoder 118 after kₜₕ transmission pᵥ is given in Eq. (4)).

In embodiments not employing ARQ, i.e., k=1, then Eq. (5) reduces to:

$${p}_{t} = {{\sum }^{N}}_{l = t + 1} ( \begin{matrix}N - 1 \\ l - 1\end{matrix} ) {{p}_{v}^{l} ( 1 - {p}_{v} )}^{N - l} \qquad Eq . ( 6 )$$

In deriving Eq. (5), the following relationship in Eq. (7) is used:

$$( \begin{matrix}N \\ l\end{matrix} ) = \frac{N !}{l ! ( N - l ) !} ⇒ \frac{l}{N} ( \begin{matrix}N \\ l\end{matrix} ) = ( \begin{matrix}N - 1 \\ l - 1\end{matrix} ) \qquad Eq . ( 7 )$$

As seen Eq. (5) and Eq. (6), the target BER pₜ is given as a function of the BER at the output of the MAC FEC decoder 118, pᵥ. Next, the BER pᵥ at the output of the PHY FEC decoder 116 is derived in terms of the target BER pₜ (Step 204 of FIG. 2).

In embodiments without ARQ, i.e., k=1, Eq. (5) for pₜ is rewritten as follows:

$${p}_{t} = {p}_{v}^{t + 1} {{\sum }^{N}}_{l = t + 1} ( \begin{matrix}N - 1 \\ l - 1\end{matrix} ) {{p}_{v}^{l - t - 1} ( 1 - {p}_{v} )}^{N - l} \qquad Eq . ( 8 )$$

Considering the function ƒ(pᵥ) in Eq. (9) below:

$$f ( {p}_{v} ) {{= \sum }^{N}}_{l = t + 1} ( \begin{matrix}N - 1 \\ l - 1\end{matrix} ) {{p}_{v}^{l - t - 1 -} ( 1 - {p}_{v} )}^{N - l} \qquad Eq . ( 9 )$$

and since 0≦pᵥ≦1, expanding ƒ(pᵥ) reveals that it can be approximated as:

$$f ( {p}_{v} ) ≅ f ( 0 ) = ( \begin{matrix}N - 1 \\ t\end{matrix} ) = ( \begin{matrix}K + d + c - 1 \\ t\end{matrix} ) \qquad Eq . ( 10 )$$

since simulation results indicate that ignoring higher order terms of ƒ(pᵥ)'s expansion in Eq. (9) results in no more than 1% error. Note that K is the number of Reed-Solomon information bits in the Reed-Solomon codeword. Therefore, combining Eq. (8) and Eq. (10), the BER pᵥ at the output of the PHY FEC decoder 116 in terms of the target BER pt without ARQ (Step 204 of FIG. 2) becomes:

$${p}_{v} = {{p}_{t}^{\frac{1}{t + 1}} ( \begin{matrix}N - 1 \\ t\end{matrix} )}^{- \frac{1}{t + 1}} \qquad Eq . ( 11 )$$

Thus, given the target BER, pₜ, for the communication system, Eq. (11) provides the bit error rate at the output of the PHY FEC decoder 116 (e.g., a Viterbi decoder) to satisfy the target BER (no ARQ present, i.e., ARQ mechanism 120 is not used).

In embodiments employing ARQ mechanism 120 allowing k transmissions, rewriting Eq. (5), the target BER in terms of the decoder BER (Step 202 of FIG. 2) is given by:

$${p}_{t} = {{p}_{v}^{( t + 1 ) k} [ {{\sum }^{N}}_{l = t + 1} ( \begin{matrix}N \\ l\end{matrix} ) {{p}_{v}^{l - t - 1} ( 1 - {p}_{v} )}^{ N - l} ]}^{k - 1} [ {{\sum }^{N}}_{l = t + 1} ( \begin{matrix}N - 1 \\ l - 1\end{matrix} ) {{p}_{v}^{l - t - 1} ( 1 - {p}_{v} )}^{N - l} ] \qquad Eq . ( 12 )$$

Similar to the approach used without ARQ present, ƒ(pᵥ) can be expressed as:

$$f ( {p}_{v} ) = {[ {{\sum }^{N}}_{l = t + 1} ( \begin{matrix}N \\ l\end{matrix} ) {{p}_{v}^{l - t - 1} ( 1 - {p}_{v} )}^{ N - l} ]}^{k - 1} [ {{\sum }^{N}}_{l = t + 1} ( \begin{matrix}N - 1 \\ l - 1\end{matrix} ) {{p}_{v}^{l - t - 1} ( 1 - {p}_{v} )}^{N - l} ] \qquad Eq . ( 13 )$$

and since simulation results again indicate that ignoring higher order terms of ƒ(pᵥ)'s expansion in Eq. (13) results in no more than 1% error, then Eq. (13) can be approximated in Eq. (14) as:

$$f ( {p}_{v} ) ≅ f ( 0 ) = {( \begin{matrix}N \\ t + 1\end{matrix} )}^{k - 1} ( \begin{matrix}N - 1 \\ t\end{matrix} ) \qquad Eq . ( 14 )$$

Therefore, combining Eq. (12) and Eq. (14), the PHY decoder BER, pᵥ, in terms of the target BER, pₜ, with ARQ present (Step 204 of FIG. 2) becomes:

$${p}_{v} = {{p}_{t}^{\frac{1}{k ( t + 1 )}} ( \begin{matrix}N \\ t + 1\end{matrix} )}^{- \frac{k - 1}{k ( t + 1 )}} {( \begin{matrix}N - 1 \\ t\end{matrix} )}^{- \frac{1}{k ( t + 1 )}} \qquad Eq . ( 15 )$$

Again, given the target BER, pₜ, for the communication system, Eq. (15) provides the bit error rate at the output of PHY FEC decoder 116 (e.g., a Viterbi decoder) to satisfy the target BER (with ARQ present). Therefore, Eq. (11) and Eq. (15) represent the result of Step 204 in FIG. 2 without ARQ and with ARQ present, respectively, according to one embodiment of the invention.

Now that the BER at the output of the PHY FEC decoder 116, pᵥ, has been derived in terms of the target BER pₜ (Step 204 of FIG. 2), the next step in the analytical process is to derive pᵥ in terms of the uncoded BER, p_{b}, at the output of the demodulator (Step 206 of FIG. 2). Thus, the focus is shifted from the data link control layer (MAC layer) to the PHY layer.

Let d_{free} denote the free distance of the PHY FEC decoder 116 (e.g., a Viterbi decoder) associated with a (Nᵥ, Kᵥ) PHY FEC encoder 108, in this embodiment a convolutional encoder, where Kᵥ is the number of information bits and Nᵥ is the length of the codeword generated by the PHY FEC encoder 108. Then the average number of bit errors in a codeword that can be corrected by the PHY FEC decoder 116, tᵥ, is:

$${t}_{v} = ⌊ \frac{{d}_{free} + 1}{2} ⌋ \qquad Eq . ( 16 )$$

Now, assuming that the BER at the output of the demodulator 114, i.e., the uncoded BER, is p_{b} (i.e., channel introduces uncoded bit error rate p_{b}), then pᵥ can be derived in terms of p_{b} (Step 206 of FIG. 2) as:

$${p}_{v } {{\sum }^{{N}_{v}}}_{l = {t}_{v} + 1} ( \begin{matrix}{N}_{v} - 1 \\ l - 1\end{matrix} ) {{p}_{b}^{l} ( 1 - {p}_{b} )}^{ {N}_{v} - l} \qquad Eq . ( 17 )$$

Next, based upon Eq. (17), p_{b} can be derived as a function of pᵥ (Step 208 of FIG. 2) as follows:

$${p}_{b} = {{p}_{v}^{\frac{1}{{t}_{v} + 1}} ( \begin{matrix}{N}_{v} - 1 \\ {t}_{v}\end{matrix} )}^{- \frac{1}{{t}_{v} + 1}} \qquad Eq . ( 18 )$$

Finally, substituting pᵥ in terms of pₜ as derived in Eq. (15) for pᵥ in Eq. (18) (Step 210 of FIG. 2), the uncoded BER p_{b} as a function of coded target BER pₜ is given as follows:

$${p}_{b} = {[ {{p}_{t}^{\frac{1}{k ( t + 1 )}} ( \begin{matrix}N \\ t + 1\end{matrix} )}^{- \frac{k - 1}{k ( t + 1 )}} {( \begin{matrix}N - 1 \\ t\end{matrix} )}^{- \frac{1}{k ( t + 1 )}} ]}^{\frac{1}{{t}_{v} + 1}} {( \begin{matrix}{N}_{v} - 1 \\ {t}_{v}\end{matrix} )}^{\frac{- 1}{{t}_{v} + 1}} \qquad Eq . ( 19 )$$

where pₜ is the target BER, k is the number of transmissions including ARQ, t is the number of bit errors that the MAC FEC decoder 118 can correct, tᵥ is the average number of bit errors in a codeword that can be corrected by the PHY FEC decoder 116, N is the length of the frame in bits, and Nᵥ is the length of the codeword generated by the PHY FEC encoder 108. Eq. (19) represents the uncoded BER in terms of the given target BER in a system using forward error correction (in the PHY layer and the MAC layer with error detection) and ARQ.

In embodiments not using ARQ, i.e., k=1, then the uncoded BER in terms of the target BER (Step 210 of FIG. 2) can be expressed as follows:

$${p}_{b} = {[ {{p}_{t}^{\frac{1}{t + 1}} ( \begin{matrix}N - 1 \\ t\end{matrix} )}^{- \frac{1}{t + 1}} ]}^{\frac{1}{{t}_{v} + 1}} {( \begin{matrix}{N}_{v} - 1 \\ {t}_{v}\end{matrix} )}^{\frac{- 1}{{t}_{v} + 1}} \qquad Eq . ( 20 )$$

Thus, Eq. (19) and Eq. (20) provide closed form solutions to the problem of determining the uncoded BER at the output of a demodulator 114 in a system including forward error correction and ARQ (Eq. (19)). All of the variables in Eq. (19) and Eq. (20) are defined by the standard. Thus, the parameters pₜ, k, t, tᵥ, N and Nᵥ are known and depend on the system.

Referring next to FIG. 3, a simplified block diagram is shown of a communication system including the transmitter 124 and the receiver 126 communicating over forward and reverse communication channels and implementing several embodiments of the invention. The transmitter 124 sends signaling to the receiver 126 via the forward communication channel 302 (also referred to as the forward channel 302) and receives signaling back from the receiver 126 via the reverse communication channel 304 (also referred to as the reverse channel 304 or the feedback channel).

In preferred embodiments, the transmitter 124 and the receiver 126 are part of a wireless LAN and use orthogonal frequency division multiplexing (OFDM), e.g., such as described in IEEE 802.11a. OFDM communication uses multiple subcarriers and transmits one M-QAM symbol in each subcarrier. It is noted that the communications may be according to other known multiplexing schemes, e.g., single carrier schemes or other multicarrier schemes as known in the art. According to several embodiments of the invention, the receiver 126 determines the uncoded BER at the output of its demodulator based upon the target BER and other system parameters as provided above in Eq. (19) and Eq. (20). This uncoded BER is then used to determine the optimum number of bits/symbol (e.g., optimum number of bits/subcarrier for a multi-carrier system, such as OFDM) that should be assigned at the modulator of the transmitter 124. Thus, the receiver 126 determines the optimum number of bits/symbol that are supportable by the forward channel 302 depending on the channel conditions. This information is then fed back to the transmitter 124 via the reverse channel 304, so that the modulator may assign the optimum number of bits/symbol in subsequent frames. In multiple carrier communication systems, such as OFDM, the receiver 124 determines the optimum number of bits/subcarrier that are supportable by the forward channel 302, which is generically referred to as the optimum number of bits/symbol. In single carrier embodiments, an optimum number of bits/carrier is determined, which is also referred to generically as an optimum number of bits/symbol.

Referring concurrently to FIG. 1, in OFDM-based embodiments when the transmitter 124 is an OFDM transmitter and the receiver 126 is an OFDM receiver, in an OFDM-based modem, each OFDM symbol is a superposition of Nₛ QAM waveforms or subcarriers. Each QAM signal is transmitted in one of the Nₛ subcarriers. Considering an M-QAM receiver 126 and given a measurement of the channel conditions for each subcarrier at the receiver 126, it is desired to determine the probability of error at the output of the M-QAM demodulator 114. It is noted that any one of metrics known to those in the art may be used to provide a measurement of the channel conditions, such as measurements of the signal-to-interference ratio (SIR), the signal-to-noise ratio (SNR), distortion levels, etc. In preferred embodiment, a measurement of the SIR is taken for each subcarrier. Assuming that the code rate for the PHY FEC encoder 108 is

$${r}_{i} = \frac{{K}_{v}}{{N}_{v}} ,$$

where Kᵥ is the number of information bits and Nᵥ is the length of the codeword generated by the PHY FEC encoder 108, the following statement holds:

R_{b}=rₗR_{c}=rₗ(log₂ M)Rₛ Eq. (21)

where R_{b} is the raw information bit rate at the input of the PHY FEC encoder 108 and R_{c} is coded information bit rate at the input of the modulator 110, M is the number of QAM symbols or M in the M-QAM modulation selected at the modulator 110, and Rₛ is the symbol rate at the output of the modulator 110.

Therefore, with Rₛ=W and I+N=N₀W (where I is interference, N is noise, and N₀ is the effective noise plus interference spectral density) the following equalities for the SIR at the receiver 126 hold:

$$γ = \frac{P}{I + N} = \frac{{E}_{s}}{{N}_{0}} = ( {log}_{2} M ) \frac{{E}_{c}}{{N}_{0}} = ( {log}_{2} M ) \frac{{K}_{v}}{{N}_{v}} \frac{{E}_{b}}{{N}_{0}} \qquad Eq . ( 22 )$$

where Eₛ is the energy per M-QAM symbol (output of the M-QAM modulator 110), E_{c} is the energy per coded bit (output of the PHY FEC encoder 108), and E_{b} is the energy per uncoded bit (input to the PHY FEC coder 108). Let b=log₂ M and γ denote the M-QAM symbol SIR. Then, it follows that for b even, the exact M-QAM symbol-error-rate (SER), p_{M}, is:

$$\begin{matrix}{p}_{M} = 1 - {[ 1 - ( 1 - {2}^{- b / 2} ) erfc ( \sqrt{\frac{3 γ}{{2}^{b + 1} - 2}} ) ]}^{2} \\ or & Eq . ( 23 ) \\ {p}_{M} = [ ( 1 - {2}^{- b / 2} ) erfc ( \sqrt{\frac{3 γ}{{2}^{b + 1} - 2}} ) ] [ 2 - ( 1 - {2}^{- b / 2} ) erfc ( \sqrt{\frac{3 γ}{{2}^{b + 1} - 2}} ) ] & Eq . ( 24 )\end{matrix}$$

If the M-QAM modulator 110 maps its input bits to M-QAM symbols using a Gray code (i.e., the Hamming distance between each QAM symbol and its neighbors is one), and assuming that the most probable errors are single bit errors, then the uncoded BER p_{b} in terms of p_{M} can be expressed as:

$${p}_{b} = \frac{1}{b} {p}_{M} \qquad Eq . ( 25 )$$

Gray coding provides the minimum Hamming distance (MHD) for each QAM symbol with its neighbors. If coding other than Gray coding is used, the probability of bit error due to decoding a QAM symbol in error would increase. For a general case, p_{b}=ρ(b)p_{M}, where ρ(b) is a function of b number of bits per QAM symbol and also a function of how the bits are assigned to the QAM symbols and

$$ρ ( b ) ⟩ \frac{1}{b} .$$

The function ρ(b) can be approximated by

$$\frac{1}{α b}$$

where 0<α≦1.

The above relationships specific to OFDM communications including those as defined in Eqs. (21)-(25) are well known in the art, thus further explanation is not required.

Now, let γᵢ denote the signal-to-interference ratio (SIR) for the i^{th} subcarrier in linear scale, where the subcarrier index i=1,2,3, . . . ,Nₛ, where Nₛ≧1 and is the total number of subcarriers (one M-QAM symbol is transmitted per each subcarrier). It is noted that when referring to embodiments employing a single carrier transmission scheme, γᵢ refers to the SIR of the single carrier for the symbol (i.e., in such case, Nₛ=1). As is commonly done in OFDM receivers, this quantity γᵢ is measured for each subcarrier at the receiver 126. Furthermore assume that bᵢ bits are allocated to the i^{th} subcarrier. Now combining Eq. (24) and Eq. (25), the uncoded BER p_{b} can be expressed in terms of γᵢ as follows:

$${p}_{b} = \frac{1}{{b}_{i}} [ ( 1 - {2}^{- {b}_{i} / 2} ) erfc ( \sqrt{\frac{3 {γ}_{i}}{{2}^{{b}_{i} + 1} - 2}} ) ] [ 2 - ( 1 - {2}^{- {b}_{i} / 2} ) erfc ( \sqrt{\frac{3 {γ}_{i}}{{2}^{{b}_{i} + 1} - 2}} ) ] \qquad Eq . ( 26 )$$

It is noted that for a general case not using Gray coding, Eq. (26) can be expressed as:

$${p}_{b} = ρ ( b ) [ ( 1 - {2}^{- {b}_{i} / 2} ) erfc ( \sqrt{\frac{3 {γ}_{i}}{{2}^{{b}_{i} + 1} - 2}} ) ] [ 2 - ( 1 - {2}^{- {b}_{i} / 2} ) erfc ( \sqrt{\frac{3 {γ}_{i}}{{2}^{{b}_{i} + 1} - 2}} ) ] \qquad Eq . ( 27 )$$

where ρ(b)=1/αb. In the example of Eq. (26), α=1.

Now, substituting p_{b} as defined in Eq. (19) in a system with FEC and ARQ (or alternatively substituting p_{b} as defined in Eq. (20) in a system with FEC and no ARQ) for p_{b} in Eq. (26), a final closed form equation for an optimal bit loading algorithm can be expressed as:

$${[ {{p}_{t}^{\frac{1}{k ( t + 1 )}} ( \begin{matrix}N \\ t + 1\end{matrix} )}^{- \frac{k - 1}{k ( t + 1 )}} {( \begin{matrix}N - 1 \\ t\end{matrix} )}^{- \frac{1}{k ( t + 1 )}} ]}^{\frac{1}{{t}_{v} + 1}} {( \begin{matrix}{N}_{v} - 1 \\ {t}_{v}\end{matrix} )}^{\frac{- 1}{{t}_{v} + 1}} = \frac{1}{{b}_{i}} [ ( 1 - {2}^{- {b}_{i} / 2} ) erfc ( \sqrt{\frac{3 {γ}_{i}}{{2}^{{b}_{i} + 1} - 2}} ) ] [ 2 - ( 1 - {2}^{- {b}_{i} / 2} ) erfc ( \sqrt{\frac{3 {γ}_{i}}{{2}^{{b}_{i} + 1} - 2}} ) ] \qquad Eq . ( 28 )$$

where pₜ is the target BER, k is the number of transmissions including ARQ, t is the number of bit errors that the MAC FEC decoder 118 can correct, tᵥ is the average number of bit errors in a codeword that can be corrected by the PHY FEC decoder 116, N is the length of the frame in bits, Nᵥ is the length of the codeword generated by the PHY FEC encoder 108, bᵢ is the number of bits/subcarrier (i.e., generically, bᵢ is the number of bits/symbol), and γᵢ is the measured SIR for the i^{th} subcarrier in linear scale. It is noted that generically, γᵢ is the measurement of the channel conditions or channel condition metric for the i^{th} subcarrier, and may be a measurement of SIR, SNR, distortion level, or other channel condition metric. It is also noted that generically, the subscript i is the subcarrier index of the symbol, where i=1, 2, 3 . . . , Nₛ, where Nₛ≧1 and is the total number of subcarriers. For example, in a single carrier transmission scheme the term subcarrier as used above means carrier and Nₛ=1, and in a multiple carrier scheme, Nₛ>1. In accordance with one embodiment using OFDM according to IEEE 802.11a, the number of subcarriers is Nₛ=48, where i=1,2,3, . . . ,48. Therefore, the closed form solutions presented herein as Eq. (28) and below in Eq. (29) are intended to apply to both single carrier and multicarrier transmission schemes.

It is noted that in embodiments not employing ARQ, i.e., k=1, the left side of Eq. (28) is replaced with Eq. (20) and becomes:

$${[ {{p}_{t}^{\frac{1}{t + 1}} ( \begin{matrix}N - 1 \\ t\end{matrix} )}^{- \frac{1}{t + 1}} ]}^{\frac{1}{{t}_{v} + 1}} {( \begin{matrix}{N}_{v} - 1 \\ {t}_{v}\end{matrix} )}^{\frac{- 1}{{t}_{v} + 1}} = \frac{1}{{b}_{i}} [ ( 1 - {2}^{- {b}_{i} / 2} ) erfc ( \sqrt{\frac{3 {γ}_{i}}{{2}^{{b}_{i} + 1} - 2}} ) ] [ 2 - ( 1 - {2}^{- {b}_{i} / 2} ) erfc ( \sqrt{\frac{3 {γ}_{i}}{{2}^{{b}_{i} + 1} - 2}} ) ] \qquad Eq . ( 29 )$$

Now, solving Eq. (28) or Eq. (29) (depending on whether or not the system includes ARQ) for bᵢ in a numerical fashion results in finding the optimal bit allocation for the i^{th} subcarrier (where i=1, 2, 3, . . . ,Nₛ) supportable by the channel based upon the channel conditions and the target BER to be met. It is noted that in some embodiments, Eq. (28) is rather complex to be solved on the fly for each subcarrier and finish the computations before the end of the burst in a receiver 126. Therefore, in preferred embodiments, Eq. (28) is solved offline for many variations of γᵢ and a lookup table or graph is created based on the system parameters (e.g., pₜ, k, t, tᵥ, N and Nᵥ) and the target BER pₜ in the system. This SIR/Bit Allocation lookup table is then stored in memory at the receiver 126.

Advantageously, in some embodiments, the OFDM receiver 126 measures the SIR (i.e., γᵢ) over each of the Nₛ subcarriers and finds the appropriate bit allocation (i.e., bᵢ) for each subcarrier using the SIR/Bit Allocation lookup table for the given target BER. However, it is noted that the receiver may use other appropriate measurements of the channel conditions. Thus, in this embodiment, the receiver 126 includes a SIR/Bit Allocation table based on the required target BER and other system parameters, such as N (N=K+c+d), K, t, Kᵥ, tᵥ, and k. The receiver 126 will send the Nₛ requested bit allocations (for Nₛ subcarriers) as a bit allocation vector over the feedback or reverse channel 304 to the transmitter 124. The transmitter 124 uses this vector for bit allocation over subcarriers for the next transmission frame.

In multiuser communication systems, such as in a wireless LAN communication system, these methods of optimum bit loading may be performed and optimized at each individual receiver 126 in the network. It is noted that in some embodiments, the optimum bit loading algorithms are only applied to data channels, and not control or broadcast channels found in multiuser communication systems.

In an OFDM system, the total number of bits carried in one OFDM symbol over all Nₛ subcarriers is given as:

$${b}_{total} = {\sum }_{i = 1}^{{N}_{s}} {b}_{i} \qquad Eq . ( 30 )$$

where bᵢ, i=1,2, . . . , Nₛ is the solution of Eq. (28) (or alternatively, the solution to Eq. (29)), the optimal bit allocation for the i^{th} subcarrier. Eq. (28) can be solved for different system parameters such as N (N=K+c+d), K, t, Kᵥ, tᵥ, and k (number of ARQ retransmissions). By varying these parameters, the parameters can be optimized for both the physical layer as well as the data link layer, such as optimum values for the length of the convolutional code (FEC) Nᵥ, the optimum length of the Reed-Solomon code (FEC) N, and the optimum number of the transmissions k including ARQ. Again, in some embodiments, this process is done offline in the system design process to find the best system parameters before hardware implementations (these parameters will be fixed after system optimizations in the system design process).

In other embodiments, and depending on the computational processing power available at the receiver 126, or when fast software radios become more feasible, the physical layer parameters can be calculated in real time and the changes can be applied on the fly, such that this method of optimizing the system parameters can be performed on the fly.

Advantageously, this approach provides a closed form solution for jointly optimizing the parameters of the physical layer (PHY) and data link layer (DLC or MAC) in a general communication system. Eq. (28) and Eq. (29) provide a robust technique for performance optimization in OFDM wireless modems. The interaction of the PHY layer and DLC layer has great impacts on overall performance of a modem (specially crucial for wireless modems because of the unreliable time varying wireless channel). Furthermore, the optimum bit loading can be determined to maximize throughput while at the same time meeting the required target BER and without “overengineering” the system by adding unnecessary margins. Using Eq. (28) or Eq. (29), a system designer can achieve the required target BER in the system without wasting important resources in the system, such as transmit power. This in turn leads to less interference in the system, which will improve the overall system capacity.

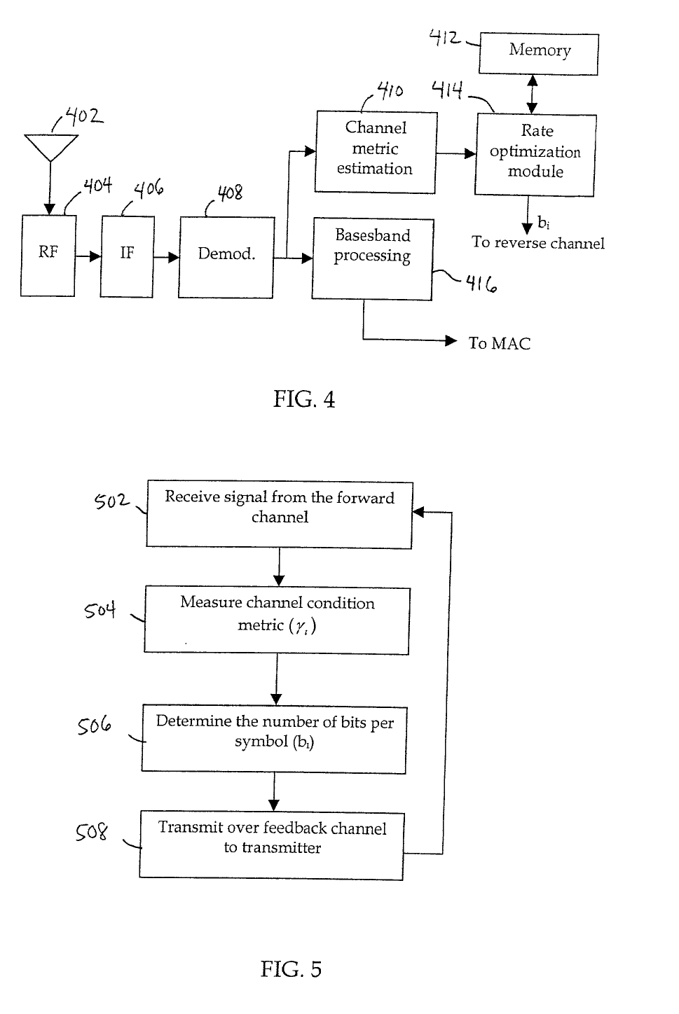

Referring next to FIG. 4, a block diagram is shown of one embodiment of the receiver of FIG. 3 used to determine an optimum number of bits/symbol supportable by the communication channel for communications from the transmitter based on measurements of the channel conditions at the receiver.

Shown is the receiver 126 including an antenna 402, a radio frequency portion 404 (hereinafter referred to as the RF portion 404), an intermediate frequency portion 406 (hereinafter referred to as the IF portion 406), a demodulator 408, a channel metric estimation module 410, a rate optimization module 414, a memory 412 and a baseband processing portion 416.

The antenna 402 receives communications from the transmitter over the forward channel and couples to the RF portion 404. Thus, a signal is received from the forward channel. The signaling is converted to IF at the IF portion 406. Next, the signal is demodulated at the demodulator 408 as is well known in the art. It is noted that in an embodiment using OFDM communications, the demodulator 408 includes an N-point fast Fourier transform (also referred to as the N-point FFT or simply as an FFT). The signal is then forwarded to the baseband processing portion 416.

In parallel to the baseband processing, a metric of the channel conditions is taken at the channel metric estimation module 410. The metric used may be any metric known in the art, such as SIR, SNR, distortion, etc. In preferred embodiment, channel metric estimation module 410 measures the SIR for each symbol, e.g., γᵢ of Eq. (28) and Eq. (29). In embodiments using OFDM, the SIR is measured for each subcarrier. It is noted that although the channel metric estimation module 410 performs a measurement taken at baseband, it is well understood that the channel metric estimation 410 could occur at IF.

This measured or estimated metric, e.g., SIR, is used to determine the optimum number of bits/symbol supportable by the forward channel depending on the channel conditions by the rate optimization module 414. It is noted that one symbol will be transmitted in each subcarrier, according to a single carrier or a multicarrier transmission scheme. Thus, the rate optimization module 414 performs the calculations in Eq. (28) or Eq. (29) (i.e., the rate optimization module performs the calculations of Eq. (19) and Eq. (20)) to determine the optimum number of bits/symbol bᵢ (e.g., the optimum number of bits/subcarrier bᵢ for OFDM) supportable by the channel depending on the channel conditions. Thus, the rate optimization module 414 should also have as inputs the various parameters also needed to solve Eq. (28) and Eq. (29), e.g., pₜ, N, K, t, Kᵥ, tᵥ, and k (including the ARQ mechanism). Some of these parameters are defined in the system and others are variable. For example, in one embodiment, pₜ, N, K, t, Kᵥ, tᵥ are defined (however, N and K may be variable) and k is variable.

In some embodiments, many of the calculations, e.g., the calculations in Eq. (19) and Eq. (20) required to solve Eq. (28) and Eq. (29), are performed offline and stored as a lookup table in the memory 412. Thus, in these embodiments, the rate optimization module 414 looks up the value for bᵢ corresponding to the estimated channel metric, e.g., SIR γᵢ, the target BER pₜ and the other system parameters in a lookup table stored in memory 412. Then, the rate optimization module 414 transmits the optimum number of bits/symbol bᵢ back to the transmitter via the reverse channel.

Referring next to FIG. 5, a flowchart is shown that illustrates the steps performed by the receiver 126 of FIG. 4 according to one embodiment of the invention. Initially, a signal is received from the forward channel (Step 502 of FIG. 5). In one embodiment, this signal is an OFDM signal representing a frame of data and containing multiple OFDM symbols. However, it is noted that in alternative embodiments, the symbol may be a single carrier symbol or another multicarrier symbol, as known in the art. The signal is received at an OFDM receiver, e.g., receiver 126. Next, a channel condition metric is measured, the channel condition metric being an estimation of the channel conditions (Step 504 of FIG. 5). In one embodiment, the estimated or measured channel condition metric is the signal-to-interference ratio (SIR) γᵢ; however, it is understood that any number of known channel metrics may be used. In embodiments using OFDM, the SIR is estimated or measured for each subcarrier of the OFDM signal. This is done, for example, at the channel metric estimation module 410 of FIG. 4.

Next, the optimum number of bits/symbol bᵢ are determined depending on the channel conditions (Step 506 of FIG. 5). In embodiments using OFDM, the optimum number of bits/ subcarrier bᵢ is determined. In one embodiment, Eq. (28) or Eq. (29) is solved. Eq. (28) and Eq. (29) provide a closed form solution for the optimum number of bits/symbol (e.g., bits/subcarrier) supportable by the channel based on the measured channel condition metric (e.g., signal-to-interference ratio (SIR) γᵢ), target BER pₜ, the number of transmissions including ARQ k, the number of bit errors correctable by the MAC FEC decoder t, the average number of bit errors in a codeword correctable by the PHY FEC decoder tᵥ, the bit length of the frame N, and the length of the codeword generated by the PHY FEC encoder Nᵥ.

In several embodiments, these equations are solved offline given the target BER and other system parameters for various measured channel metrics, e.g., for various measured SIRs. These offline calculations are stored as a lookup table in the receiver. Thus, in these embodiments, the optimum number of bits/symbol is determined by looking up the appropriate value based on the measured channel metric in memory. Step 506 may be performed, for example, by the rate optimization module 414 and memory 412 of FIG. 4.

It is noted that although the uncoded BER p_{b} is not expressly determined in the calculation of bᵢ in Eq. (28) or Eq. (29), in some embodiments, within Step 506 of FIG. 5, the uncoded BER p_{b} is expressly determined, e.g., Eq. (19) or Eq. (20) is expressly solved for the uncoded BER. Thus, the rate optimization module 414 may expressly determine the uncoded BER p_{b} and the optimum number of bits/symbol bᵢ supportable by the channel. Again, the rate optimization module 414 may determine the uncoded BER p_{b} by solving either Eq. (19) or Eq. (20) directly, or by looking up the value of p_{b} in a table stored in memory 412. In embodiments where such calculations are performed offline, the uncoded BER becomes an entry in the lookup table based on different variations of the parameters defined by the system.

Next, once determined, the optimum number of bits/symbol is transmitted back to the transmitter via a reverse channel (Step 508 of FIG. 5). This allows the modulator at the transmitter to adjust the number of bits assigned to each symbol (e.g., to each subcarrier for OFDM embodiments) for the next transmission frame. The entire process is then repeated at desired intervals. For example, Steps 502 through 508 may be performed for every frame received at the receiver, or for every m frames as desired. Thus, the optimum number of bits/subcarrier at the transmitter may be updated every frame or every m^{th} frame. This is particularly useful in time variant, unreliable wireless channels. It is noted that it is generally assumed that the transmitter keeps its transmit power at a relatively fixed level for a period of time, e.g., several hundred MAC frames. This means that the transmitter only employs a very slow power setting algorithm.

Furthermore, in OFDM embodiments, the optimum number of bits/symbol may be optimized and updated for each subcarrier. Thus, in a subsequent frame, each subcarrier of the OFDM waveform may be assigned a different number of bits, i.e., each subcarrier may have different modulations. Alternatively, each subcarrier of the OFDM waveform may be assigned the same number of bits/subcarrier.

Depending on the channel condition (e.g., in terms of the SIR) for a given subcarrier, it would be optimal to pack more bits in good channels (e.g., with high SIR) and send fewer bits through subcarriers in poor channels (e.g., with poor SIR). The method of FIG. 5 provides one embodiment of a closed form solution for an optimum bit allocation algorithm based on the channel conditions between a given transmitter and a given receiver in a system with forward error correction in the physical layer, forward error correction and in the data link layer (DLC) and error detection capability (CRC), and an automatic repeat request (ARQ) mechanism.

Furthermore, the optimum bit loading methods maximize throughput while at the same time meeting the required target BER and without “overengineering” the system by adding unnecessary margins. In comparison to conventional systems using gain margins, the present techniques allow for less expensive receiver designs. Using Eq. (28) or Eq. (29), a system designer can optimize throughput and achieve the required target BER in the system without wasting important resources in the system, such as transmit power. This in turn leads to less interference in the system, which will improve the overall system capacity.

While the invention herein disclosed has been described by means of specific embodiments and applications thereof, numerous modifications and variations could be made thereto by those skilled in the art without departing from the scope of the invention set forth in the claims.

What is claimed is:

1. A method comprising:
obtaining a target bit error rate required at a receiver; and
determining an uncoded bit error rate at an output of a demodulator of the receiver based upon at least the target bit error rate, the target bit error rate defined as the bit error rate to be achieved after the completion of forward error correction at the receiver.

2. The method of claim 1 wherein the target bit error rate is defined as the bit error rate to be achieved after the completion of the forward error correction and automatic repeat request at the receiver.

3. The method of claim 2 wherein the target bit error rate is defined as the bit error rate to be achieved after the completion of forward error correction in the physical layer and forward error correction in the medium access control layer and the automatic repeat request at the receiver.

4. The method of claim 3 wherein the determining step comprises determining the uncoded bit error rate at the output of the demodulator of the receiver based upon the target bit error rate, a number of transmissions including the automatic repeat request, a number of bit errors correctable by forward error correction decoding in the medium access control layer, an average number of bit errors in a codeword correctable in forward error correction decoding in the physical layer, a number of bits in a given frame, and a length of the codeword generated in forward error correction encoding at the physical layer at a transmitter.

5. The method of claim 4 wherein the determining step comprises determining the uncoded bit error rate, p_{b}, according to the equation:
$${p}_{b} = {[ {( {p}_{t}^{\frac{1}{k ( t + 1 )}} ( \frac{N}{t + 1} ) )}^{- \frac{k - 1}{k ( t + 1 )}} {( \frac{N - 1}{t} )}^{- \frac{1}{k ( t + 1 )}} ]}^{- \frac{1}{{t}_{v} + 1}} {( \frac{{N}_{v} - 1}{{t}_{v}} )}^{- \frac{- 1}{{t}_{v} + 1}}$$
where pₜ is the target bit error rate, N is the number of bits in a given frame, k is the number of transmissions of the frame including the automatic repeat request, t is the number of bits in error, tᵥ is the average number of errors in the codeword that can be corrected in the forward error correction decoding in the medium access control layer, and Nᵥ is the length of the codeword used in the forward error correction decoding in the physical layer.

6. The method of claim 1 wherein the determining step comprises determining the uncoded bit error rate, p_{b}, according to the equation:
$${p}_{b} = {[ {( {p}_{t}^{\frac{1}{( t + 1 )}} ( \frac{N - 1}{t} ) )}^{- \frac{1}{( t + 1 )}} ]}^{- \frac{1}{{t}_{v} + 1}} {( \frac{{N}_{v} - 1}{{t}_{v}} )}^{\frac{- 1}{{t}_{v} + 1}}$$
where pₜ is the target bit error rate, N is a number of bits in a given frame, t is a number of bits in error, tᵥ is an average number of errors in a codeword that can be corrected in forward error correction decoding in the medium access control layer, and Nᵥ is a length of the codeword used in the forward error correction decoding in the physical layer.

7. The method of claim 1 further comprising storing the uncoded bit error rate in a memory.

8. The method of claim 1 wherein the determining step comprises looking up the uncoded bit error rate in a memory based upon at least the target bit error rate.

9. The method of claim 8 wherein the memory contains predetermined values of the uncoded bit error rate based upon different values of the number of transmissions including automatic repeat request, a number of bit errors correctable by a forward error correction decoder in the medium access control layer at the receiver, an average number of bit errors in a codeword correctable by a forward error correction decoder in the physical layer at the receiver, an number of bits in a given frame, and a length of the codeword generated by a forward error correction encoder in the physical layer at the transmitter.

10. The method of claim 1 wherein the determining step comprises deriving a relationship between the target bit error rate and the uncoded bit error rate, the deriving the relationship step comprising:
deriving the target bit error rate in terms of a decoder bit error rate at an output of a forward error correction decoder in the physical layer of the receiver;
deriving the decoder bit error rate in terms of the target bit error rate;
deriving the decoder bit error rate in terms of the uncoded bit error rate;
deriving the uncoded bit error rate in terms of the decoder bit error rate; and
substituting the derivation of the decoder bit error rate in terms of the target bit error rate into the derivation of the uncoded bit error rate in terms of the decoder bit error rate.

11. A method comprising:
measuring a channel condition metric corresponding to a signal received from a transmitter at a receiver via a forward communication channel; and
determining an optimum number of bits/symbol supportable by the forward communication channel based upon at least the measured channel condition metric and a target bit error rate to be met at the receiver.

12. The method of claim 11 further comprising transmitting the optimum number of bits/symbol to the transmitter via a reverse communication channel.

13. The method of claim 11 wherein the measuring the channel condition metric step comprises measuring signal-to-interference ratio corresponding to the signal received from the transmitter.

14. The method of claim 11 wherein the signal comprises a multi-carrier signal including a plurality of subcarriers, wherein the measuring step comprises measuring the channel condition metric corresponding to each subcarrier of the multi-carrier signal received via the forward communication channel.

15. The method of claim 14 wherein the determining step comprises determining an optimum number of bits/subcarrier supportable by the forward communication channel based on the measured signal-to-interference ratio corresponding to each subcarrier.

16. The method of claim 15 wherein the multi-carrier signal comprises an orthogonal frequency division multiplexing (OFDM) signal including the plurality of subcarriers.

17. The method of claim 11 wherein the determining comprises determining the optimum number of bits/symbol supportable by the forward communication channel by solving the following equation for the optimum number of bits/symbol, bᵢ:
$${[ {{p}_{t}^{\frac{1}{k ( t + 1 )}} ( \begin{matrix}N \\ \\ t + 1\end{matrix} )}^{- \frac{k - 1}{k ( t + 1 )}} {( \begin{matrix}N - 1 \\ \\ t\end{matrix} )}^{- \frac{1}{k ( t + 1 )}} ]}^{\frac{1}{{t}_{v} + 1}} {( \begin{matrix}{N}_{v} - 1 \\ \\ {t}_{v}\end{matrix} )}^{\frac{- 1}{{t}_{v} + 1}} = \\ \frac{1}{{b}_{i}} [ ( 1 - {2}^{- {b}_{i} / 2} ) erfc ( \sqrt{\frac{3 {γ}_{i}}{{2}^{{b}_{i} + 1} - 2}} ) ] [ 2 - ( 1 - {2}^{- {b}_{i} / 2} ) erfc ( \sqrt{\frac{3 {γ}_{i}}{{2}^{{b}_{i} + 1} - 2}} ) ]$$
where pₜ is the target bit error rate, k is a number of transmissions including automatic repeat request, t is a number of bit errors that a forward error correction decoder in a medium access control layer in the receiver can correct, tᵥ is an average number of bit errors in a codeword that can be corrected by a forward error correction decoder in the physical layer in the receiver, N is a length of a frame in bits, Nᵥ is a length of the codeword generated by a forward error correction encoder in the physical layer of the transmitter, yᵢ is the measured channel metric, and the index i=1,2,3, . . . ,Nₛ, where Nₛ≧1 and is the total number of subcarriers.

18. The method of claim 16 wherein the determining comprises determining the optimum number of bits/symbol supportable by the forward communication channel by solving the following equation for the optimum number of bits/symbol, bᵢ:
$${[ {{p}_{t}^{\frac{1}{t + 1}} ( \begin{matrix}N - 1 \\ \\ t\end{matrix} )}^{- \frac{1}{t + 1}} ]}^{\frac{1}{{t}_{v} + 1}} {( \begin{matrix}{N}_{v} - 1 \\ \\ {t}_{v}\end{matrix} )}^{\frac{- 1}{{t}_{v} + 1}} = \\ \frac{1}{{b}_{i}} [ ( 1 - {2}^{- {b}_{i} / 2} ) erfc ( \sqrt{\frac{3 {γ}_{i}}{{2}^{{b}_{i} + 1} - 2}} ) ] [ 2 - ( 1 - {2}^{- {b}_{i} / 2} ) erfc ( \sqrt{\frac{3 {γ}_{i}}{{2}^{{b}_{i} + 1} - 2}} ) ]$$
where pₜ is the target bit error rate, t is a number of bit errors that a forward error correction decoder in the medium access control layer in the receiver can correct, tᵥ is an average number of bit errors in a codeword that can be corrected by a forward error correction decoder in the physical layer in the receiver, N is a length of a frame in bits, Nᵥ is a length of the codeword generated by a forward error correction encoder in the physical layer of the transmitter, and yᵢ is the measured channel metric, and the index i=1,2,3, . . . ,Nₛ, where Nₛ≧1 and is the total number of subcarriers.

19. The method of claim 11 wherein the determining comprises looking up in memory the optimum number of bits/symbol supportable by the forward communication channel based upon at least the measured channel metric and the target bit error rate.

20. The method of claim 19 wherein the memory contains predetermined values of the optimum number of bits/symbol based upon different values of the measured channel metric, the number of transmissions including automatic repeat request, a number of bit errors correctable by a forward error correction decoder in the medium access control layer at the receiver, an average number of bit errors in a codeword correctable by a forward error correction decoder in the physical layer at the receiver, a bit length of a frame, and a length of the codeword generated by a forward error correction encoder in the physical layer at the transmitter.

21. A receiver in a communication system comprising:
a channel metric estimation module for measuring a channel condition metric corresponding to a signal received from a communication channel; and
a rate optimization module for determining an optimum number of bits/symbol supportable by the communication channel based upon at least the measured channel condition metric and a target bit error rate to be met at the receiver.

22. The receiver of claim 21 wherein the channel metric estimation module measures the channel condition metric corresponding to each of a plurality of subcarrier of a received multi-carrier signal, and wherein the rate optimization module determines an optimum number of bits/subcarrier supportable by the communication channel.

23. The receiver of claim 21 wherein the channel metric estimation module measures a signal-to-interference ratio corresponding to the signal.

24. The receiver of claim 21 wherein the rate optimization module determines the optimum number of bits/symbol supportable by the communication channel by solving the following equation for the optimum number of bits/symbol, bᵢ:
$${[ {{p}_{t}^{\frac{1}{k ( t + 1 )}} ( \begin{matrix}N \\ \\ t + 1\end{matrix} )}^{- \frac{k - 1}{k ( t + 1 )}} {( \begin{matrix}N - 1 \\ \\ t\end{matrix} )}^{- \frac{1}{k ( t + 1 )}} ]}^{\frac{1}{{t}_{v} + 1}} {( \begin{matrix}{N}_{v} - 1 \\ \\ {t}_{v}\end{matrix} )}^{\frac{- 1}{{t}_{v} + 1}} = \\ \frac{1}{{b}_{i}} [ ( 1 - {2}^{- {b}_{i} / 2} ) erfc ( \sqrt{\frac{3 {γ}_{i}}{{2}^{{b}_{i} + 1} - 2}} ) ] [ 2 - ( 1 - {2}^{- {b}_{i} / 2} ) erfc ( \sqrt{\frac{3 {γ}_{i}}{{2}^{{b}_{i} + 1} - 2}} ) ]$$
where pₜ is the target bit error rate, k is the number of transmissions including automatic repeat request, t is a number of bit errors that a forward error correction decoder in the medium access control layer in the receiver can correct, tᵥ is an average number of bit errors in a codeword that can be corrected by a forward error correction decoder in the physical layer in the receiver, N is a length of a frame in bits, Nᵥ is a length of the codeword generated by a forward error correction encoder in the physical layer of a transmitter, and yᵢ is the measured channel condition metric, and the index i=1,2,3, . . . ,Nₛ, where Nₛ≧1 and is the total number of subcarriers.

25. The receiver of claim 21 wherein the rate optimization module determines the optimum number of bits/symbol supportable by the communication channel by solving the following equation for the optimum number of bits/symbol, bᵢ:
$${[ {{p}_{t}^{\frac{1}{t + 1}} ( \begin{matrix}N - 1 \\ \\ t\end{matrix} )}^{- \frac{1}{t + 1}} ]}^{\frac{1}{{t}_{v} + 1}} {( \begin{matrix}{N}_{v} - 1 \\ \\ {t}_{v}\end{matrix} )}^{\frac{- 1}{{t}_{v} + 1}} = \\ \frac{1}{{b}_{i}} [ ( 1 - {2}^{- {b}_{i} / 2} ) erfc ( \sqrt{\frac{3 {γ}_{i}}{{2}^{{b}_{i} + 1} - 2}} ) ] [ 2 - ( 1 - {2}^{- {b}_{i} / 2} ) erfc ( \sqrt{\frac{3 {γ}_{i}}{{2}^{{b}_{i} + 1} - 2}} ) ]$$
where pₜ is the target bit error rate, t is a number of bit errors that a forward error correction decoder in the medium access control layer in the receiver can correct, tᵥ is an average number of bit errors in a codeword that can be corrected by a forward error correction decoder in the physical layer in the receiver, N is a length of a frame in bits, Nᵥ is a length of the codeword generated by a forward error correction encoder in the physical layer of a transmitter, and yᵢ is the measured channel condition metric, and the index i=1,2,3, . . . ,Nₛ, where Nₛ≧1 and is the total number of subcarriers.

26. The receiver of claim 21 further comprising a memory coupled to the rate optimization module, the memory containing predetermined values of the optimum number of bits/symbol based upon at least different channel condition metric measurements and the target bit error rate.

27. The receiver of claim 26 wherein the rate optimization module determines the optimum number of bits/symbol by looking up the optimum number of bits/symbol in the memory based upon a measured channel condition metric and a given target bit error rate.
